(19) United States
(12) Patent Application Publication
(10) Pub. No.: US 2016/0149003 A1
(43) Pub. Date: May 26, 2016

(54) Methods of Manufacturing Semiconductor Devices

(71) Applicant: Samsung Electronics Co., Ltd., Suwon-si (KR)

(72) Inventors: Kyung-In Choi, Seoul (KR); Wook-Je Kim, Gwacheon-si (KR); Baek-Hap Choi, Anyang-si (KR); Jin-Hee Han, Ansan-si (KR); Hyun-Gi Hong, Seongnam-si (KR)

(21) Appl. No.: 14/855,533

(22) Filed: Sep. 16, 2015

(30) Foreign Application Priority Data
Nov. 24, 2014 (KR) 10-2014-0164129

(51) Int. Cl. H01L 29/10; H01L 21/265; H01L 21/266; H01L 21/8234; H01L 21/768; H01L 29/66; H01L 21/324

(52) U.S. Cl. CPC H01L 29/1054; H01L 29/6659; H01L 21/26513; H01L 21/324; H01L 21/26586; H01L 21/823431; H01L 21/823412; H01L 21/823437; H01L 21/823481; H01L 21/823418; H01L 21/76805; H01L 21/76877; H01L 21/266

(57) ABSTRACT

In methods of manufacturing a semiconductor device, a stress channel layer is formed on a semiconductor substrate. A first ion-implantation process is performed on the semiconductor substrate or the stress channel layer at a temperature ranging from about 100° C. to about 600° C. A gate structure is formed on the stress channel layer. A first source/drain region is formed at an upper portion of the stress channel layer adjacent to the gate structure.

### CROSS-REFERENCE TO RELATED APPLICATION

This U.S. non-provisional patent application claims priority under 35 USC §119 to Korean Patent Application No. 10-2014-0164129, filed on Nov. 24, 2014 in the Korean Intellectual Property Office (KIPO), the contents of which are incorporated by reference herein in their entirety.

### BACKGROUND

1. Field

Example embodiments relate to methods of manufacturing semiconductor devices. More particularly, example embodiments relate to methods of manufacturing semiconductor devices including an impurity region.

2. Description of the Related Art

To improve performances of semiconductor devices, technologies for improving carrier mobility in a channel have been researched. For example, a tensile stress or a compressive stress may be applied in a channel region of a transistor so that a mobility of electrons or holes may be increased. As a result, an operational speed of the transistor may be improved.

However, the stress applied to the channel region may be relaxed or reduced by various processes subsequently performed in a manufacture of the semiconductor device.

### SUMMARY

Example embodiments provide methods of manufacturing a semiconductor device having improved operational properties.

According to example embodiments, there is provided a method of manufacturing a semiconductor device. In the method, a stress channel layer may be formed on a semiconductor substrate. A first ion-implantation process may be formed on the semiconductor substrate or the stress channel layer at a temperature ranging from about 100° C. to about 600° C. A gate structure may be formed on the stress channel layer. A first source/drain region may be formed at an upper portion of the stress channel layer adjacent to the gate structure.

In example embodiments, the stress channel layer may include silicon (Si), silicon-germanium (SiQe) or germanium (Ge).

In example embodiments, before forming the stress channel layer, a stress relaxation buffer layer including SiGe may be formed on the semiconductor substrate. The stress channel layer may be grown from the stress relaxation buffer layer.

In example embodiments, the first ion-implantation process may be performed on the stress relaxation buffer layer before forming the stress channel layer.

In example embodiments, the first ion-implantation process may be performed at a temperature ranging from about 300° C. to about 500° C.

In example embodiments, after performing the first ion-implantation process, a thermal treatment may be performed on the stress channel layer at a temperature ranging from about 500° C. to about 1,000° C.

In example embodiments, in the formation of the first source/drain region, a second ion-implantation process may be performed on the stress channel layer at a temperature ranging from about 100° C. to about 600° C.

In example embodiments, after performing the second ion-implantation process, a third ion-implantation process may be performed by a predetermined tilting angle at a temperature ranging from about 100° C. to about 600° C. such that a halo region may be formed at an upper portion of the stress channel layer adjacent to the first source/drain region and the gate structure.

In example embodiments, an elevated source drain (ESD) layer may be grown from the first source/drain region. A fourth ion-implantation process may be performed on the ESD layer at a temperature ranging from about 100° C. to about 600° C. to form a second source/drain region.

In example embodiments, the ESD layer may include silicon, silicon carbide, silicon germanium, germanium or germanium manganese.

According to example embodiments, there is provided a method of manufacturing a semiconductor device. In the method, a stress channel layer defined by an isolation layer may be formed on a semiconductor substrate. A first ion-implantation process may be performed on the stress channel layer at a temperature ranging from about 100° C. to about 600° C. An upper portion of the isolation layer may be removed to expose the stress channel layer such that a plurality of semiconductor fins may be formed. A gate structure extending in a direction and crossing the semiconductor fins may be formed.

In example embodiments, a stress relaxation buffer layer may be formed on the semiconductor substrate before forming the stress channel layer. The stress channel layer and the stress relaxation buffer layer may be partially etched to form a trench. The isolation layer filling the trench may be formed.

In example embodiments, in the formation of the stress channel layer defined by the isolation layer, the isolation layer may be formed at an upper portion of the semiconductor substrate to form a dummy active pattern. The dummy active pattern may be removed to form a recess. A Stress relaxation buffer layer filling the recess may be formed. An upper portion of the stress relaxation buffer layer may be removed to form a stress relaxation buffer layer pattern partially filling the recess. The stress channel layer may be formed on the stress relaxation buffer layer pattern. The stress channel layer may fill a remaining portion of the recess.

In example embodiments, a stress relaxation buffer layer may be formed on the semiconductor substrate before forming the stress channel layer. The stress relaxation buffer layer may be partially etched to form a trench. The isolation layer filling the trench may be formed. An upper portion of the stress relaxation buffer layer may be removed to form a recess defined by a sidewall of the isolation layer and an upper surface of the stress relaxation buffer layer. The stress channel layer may be grown from the upper surface of the stress relaxation buffer layer. The stress channel layer may at least partially fill the recess.

In example embodiments, a second ion-implantation process may be performed on the semiconductor fins at a temperature ranging from about 100° C. to about 600° C. to form first source/drain regions at upper portions of the semiconductor fins adjacent to the gate structure.

In example embodiments, an elevated source drain (ESD) layer may be grown from the first source/drain regions. A third ion-implantation process may be performed on the ESD layer at a temperature ranging from about 100° C. to about 600° C. to form second source/drain regions.

In example embodiments, forming a preliminary contact layer may be formed on the second source/drain regions. A fourth ion-implantation process may be performed on the preliminary contact layer at a temperature ranging from about 100° C. to about 600° C. to form a contact electrically connected to at least one of the second source/drain regions.

In example embodiments, an insulating interlayer covering the second source/drain regions and the gate structure may be formed. The insulating interlayer may be partially etched to form a contact hole that may expose two neighboring second source/drain regions of the second source drain regions. The preliminary contact layer may fill the contact hole.

According to example embodiments, there is provided a method of manufacturing a semiconductor device. In the method, a plurality of active patterns defined by an isolation layer may be formed on a semiconductor substrate. The semiconductor substrate may include a group III-V compound. A first ion-implantation process may be performed on the active patterns at a temperature ranging from about 100° C. to about 600° C. such that upper portions of the active patterns are converted into semiconductor fins. A gate structure extending in a direction and crossing the semiconductor fins may be formed.

In example embodiments, a second ion-implantation process may be performed on the semiconductor fins at a temperature ranging from about 100° C. to about 600° C. using the gate structure as an implantation mask to form a source/drain region.

### BRIEF DESCRIPTION OF THE DRAWINGS

Example embodiments will be more clearly understood from the following detailed description taken in conjunction with the accompanying drawings. FIGS. 1 to 46 represent non-limiting, example embodiments as described herein.

FIGS. 1 to 10 are cross-sectional views illustrating a method of manufacturing a semiconductor device in accordance with example embodiments;

FIGS. 11 to 15 are cross-sectional views illustrating a method of manufacturing a semiconductor device in accordance with some example embodiments;

FIGS. 16 to 29 are perspective views and cross-sectional views illustrating a method of manufacturing a semiconductor device in accordance with example embodiments;

FIGS. 30 to 34 are cross-sectional views illustrating a method of manufacturing a semiconductor device in accordance with some example embodiments;

FIGS. 35 to 40 are cross-sectional views illustrating a method of manufacturing a semiconductor device in accordance with some example embodiments;

FIGS. 41 to 45 are cross-sectional views and perspective views illustrating a method of manufacturing a semiconductor device in accordance with some example embodiments; and

FIG. 46 is a broken-line graph showing values of a stress relaxation ratio measured by Experimental Examples.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Example embodiments are described herein with reference to cross-sectional or perspective illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

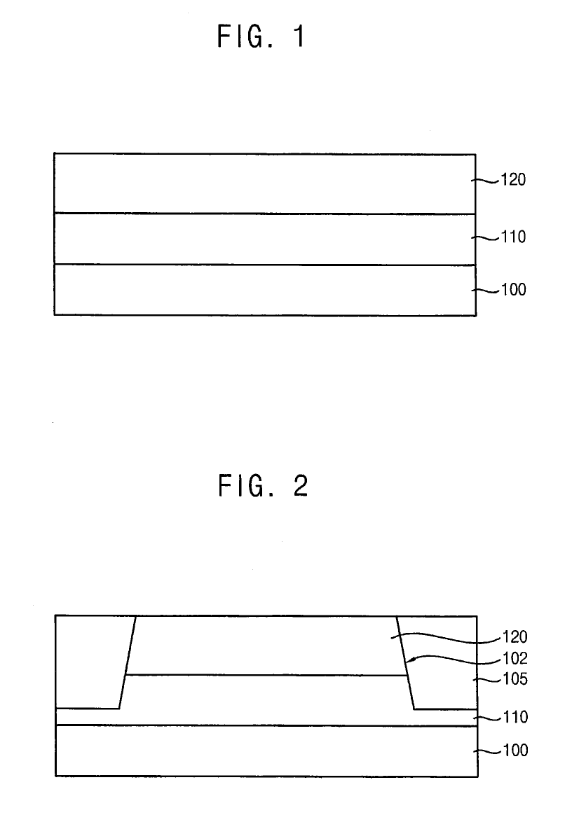

FIGS. 1 to 10 are cross-sectional views illustrating a method of manufacturing a semiconductor device in accordance with example embodiments.

Referring to FIG. 1, a stress relaxation buffer (SRB) layer 110 and a preliminary stress channel layer 120 may be formed on a semiconductor substrate 100.

The semiconductor substrate 100 may include a semiconductor material such as silicon (Si). In some embodiments, the semiconductor substrate 100 may be a silicon-on-insulator (SOI) substrate or a germanium-on-insulator (GOI) substrate.

The SRB layer 110 may include silicon containing a stress generating element. In example embodiments, the SRB layer 110 may include silicon-germanium (Si—Ge).

The SRB layer 110 may be formed by a selective epitaxial growth (SEG) process. For example, a silicon source gas and a germanium source gas may be provided on the semiconductor substrate 100. An upper surface of the semiconductor substrate 100 may serve as a seed layer, and the SRB layer 110 including Si—Ge may be formed from the seed layer.

For example, the silicon source gas may include silane (SiH₄) or dichlorosilane (SiH₂Cl₂). The germanium source gas may include germanium tetrahydride (GeH₄) or germanium tetrachloride (GeCl₄). Each of the silicon source gas and the germanium source gas may include a plurality of source compounds.

In some embodiments, a germanium content in the SRB layer 110 may range from about 10 weight percent (wt %) to about 30 wt %. For example, a flow rate of the germanium source gas provided on the semiconductor substrate 100 may be controlled so that the germanium content may be adjusted.

The preliminary stress channel layer 120 may be formed by a SEG process using the SRB layer 110 as a seed layer.

In some embodiments, the preliminary stress channel layer 120 may include silicon. For example, the above-mentioned silicon source gas may be provided on the SRB layer 110 to form the preliminary stress channel layer 120. A distance between neighboring silicon atoms in the SRB layer 110 may be increased by germanium atoms combined to the silicon atoms. In some embodiments, the preliminary stress channel layer 120 formed by growing a silicon layer from the SRB layer 110 may include a tensile silicon.

In some embodiments, the preliminary stress channel layer 120 may include Si—Ge or Ge. In this case, the preliminary stress channel layer 120 may include a compressive stress generated by Ge atoms having a relatively large crystal lattice. For example, the silicon source gas or the germanium source gas may be co-provided on the SRB layer 110, or the germanium source gas may be provided on the SRB layer 110 to form the preliminary stress channel layer 120 including Si—Ge or Ge.

In example embodiments, the SRB layer 110 and the preliminary stress channel layer 120 may be formed in-situ, e.g., in the same process chamber.

The preliminary stress channel layer 120 may have a Ge content greater than that of the SRB layer 110. In some embodiments, the Ge content of the preliminary channel layer 120 may range from about 40 wt % to about 90 wt %.

Referring to FIG. 2, an isolation layer 105 separating the preliminary stress layer 120 and the SRB layer 110 may be formed.

In example embodiments, the isolation layer 105 may be formed by a shallow trench isolation (STI) process. For example, the preliminary stress layer 120 and the SRB layer 110 may be partially removed to form a trench 102, and an insulation layer sufficiently filling the trench 102 may be formed on the preliminary stress channel layer 120. An upper portion of the insulation layer may be planarized by, e.g., a chemical mechanical polish (CMP) process until an upper surface of the preliminary stress channel layer 120 is exposed to form the isolation layer 105. The insulation layer may be formed of silicon oxide.

After the formation of the isolation layer 105, an upper region of the semiconductor substrate 100 may be divided into an active region and the field region.

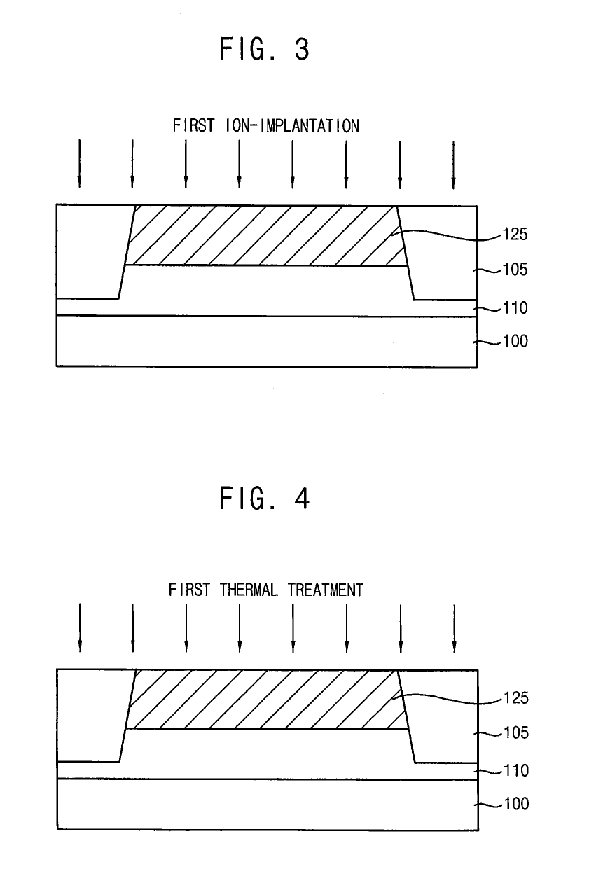

Referring to FIG. 3, a first ion-implantation process may be performed on the preliminary stress channel layer 120. Accordingly, a first impurity may be implanted so that the preliminary channel layer 120 may be converted into a stress channel layer 125.

The stress channel layer 125 may serve as a well or a channel of the semiconductor device. For example, p-type impurities such as boron (B) may be implanted by the first ion-implantation process. In this case, the stress channel layer 125 may serve as a p-type well. Alternatively, n-type impurities such as arsenic (As) or phosphorous (P) may be implanted by the first ion-implantation process. In this case, the stress channel layer 125 may serve as an n-type well.

FIG. 3 illustrates that the preliminary stress channel layer 120 may be fully converted into the stress channel layer 125. However, an upper portion of the preliminary stress channel layer 120 may be converted into the stress channel layer 125. In some embodiments, the first impurity may be propagated even into the SRB layer 110. In this case, the SRB layer 110 may be also partially converted into the stress channel layer 125.

In example embodiments, the first ion-implantation process may be performed at a temperature ranging from about 100° C. to about 600° C. In some embodiments, the first ion-implantation process may be performed at a temperature ranging from about 300° C. to about 500° C.

In a comparative example, the first ion-implantation process may be performed at a room temperature. In this case, the stress applied to the preliminary stress channel layer 120 and/or the SRB layer 110 may be relaxed or reduced by the first ion-implantation process. For example, impurity atoms from the first ion-implantation process may intervene between Si—Ge bonds, or may damage the bonds.

As a result, defects may be caused in the preliminary stress channel layer 120 and/or the SRB layer 110, and the stress channel layer 125 formed from the preliminary stress channel layer 120 may also include the defects and a relaxed stress.

However, according to example embodiments, the first ion-implantation process may be performed at a high temperature of the above-mentioned range. Thus, the defects caused by the first impurity, e.g., the damage of the Si—Ge bonds may be cured by, e.g., a partial crystallization. Further, the damaged bond may be self-cured by an activation of the first impurity at the high temperature.

If the temperature of the first ion-implantation process is less than about 100° C., a stress relaxation may not be sufficiently suppressed. If the temperature of the first ion-implantation process exceeds 600° C., the first impurity may be excessively activated to result in a damage of the preliminary stress channel layer 120 and/or the stress channel layer 125.

FIGS. 2 and 3 illustrate that the ion-implantation process is performed after forming the isolation layer (e.g., an STI first process). However, the isolation layer 105 may be formed after performing the first ion-implantation process (e.g., an STI last process).

Referring to FIG. 4, a first thermal treatment may be performed on the stress channel layer 125. The first thermal treatment may include an annealing process.

The stress channel layer 125 may be additionally crystallized by the first thermal treatment. In example embodiments, the first thermal treatment may include a low temperature annealing performed at a temperature lower than about 1,000° C.

As illustrated with reference to FIG. 3, the first ion-implantation process may be performed at a relatively high temperature so that the temperature for the subsequent annealing process may be decreased. Thus, a damage of the Si—Ge bonds and a stress relaxation therefrom caused by a high temperature annealing may be reduced or possibly avoided.

In some embodiments, the first thermal treatment may be performed at a temperature ranging from about 500° C. to about 900° C. If the temperature of the first thermal treatment is lower than about 500° C., the stress channel layer 125 may not be sufficiently crystallized, and thus may have defects therein. If the temperature of the first thermal treatment exceeds about 900° C., a stress relaxation may be caused by the high temperature in the stress channel layer 125.

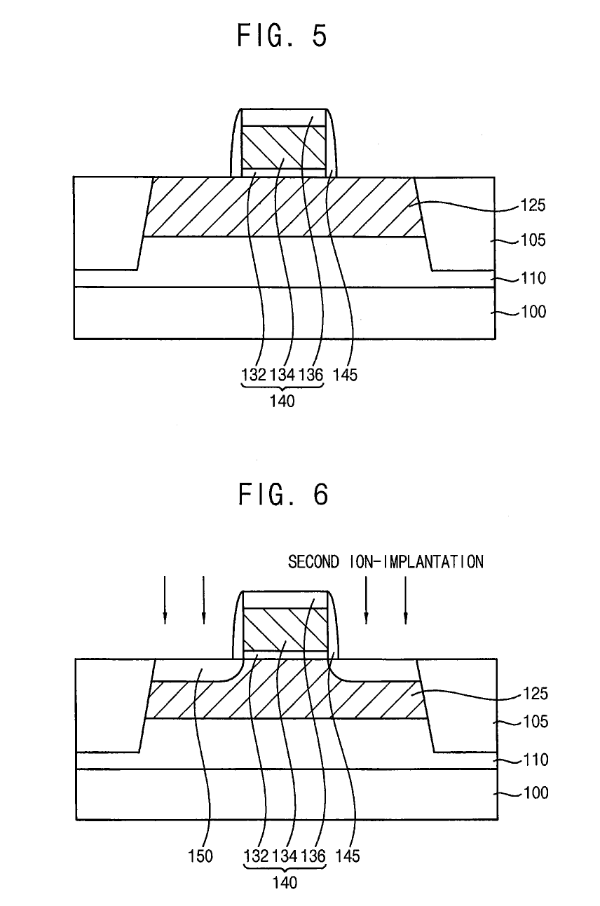

Referring to FIG. 5, a gate structure 140 may be formed on the stress channel layer 125.

For example, a gate insulation layer, a gate electrode layer and a gate mask layer may be sequentially formed on the isolation layer 105 and the stress channel layer 125. The gate mask layer may be patterned by, e.g., a photolithography process to form a gate mask 136. The gate electrode layer and the gate insulation layer may be partially removed using the gate mask 136 as an etching mask to form a gate electrode 134 and a gate insulation layer pattern 132. Accordingly, the gate structure 140 including the gate insulation layer pattern 132, the gate electrode 134 and the gate mask 136 sequentially stacked on the stress channel layer 125 may be formed.

The gate insulation layer may be formed of silicon oxide or a metal oxide. In some embodiments, the gate insulation layer may be formed by performing a thermal oxidation on an upper portion of the stress channel layer 125.

The gate electrode layer may be formed of a doped polysilicon, a metal, a metal nitride or a metal silicide. For example, the gate electrode layer may be formed using a metal such as molybdenum, titanium, tantalum, hafnium, zirconium, aluminum, tungsten, etc., a nitride of the metal, a silicide of the metal, or a combination thereof. The gate mask layer may be formed of silicon nitride.

The gate insulation layer, the gate electrode layer and the gate mask layer may be formed by, e.g., a chemical vapor deposition (CVD) process, a physical vapor deposition (PVD) process, or an atomic layer deposition (ALD) process.

In some embodiments, a gate spacer 145 may be further formed on a sidewall of the gate structure 140.

For example, a spacer layer covering the gate structure 140 may be formed on the isolation layer 105 and the stress channel layer 125. The spacer layer may be anisotropically etched to form the gate spacer 145. The spacer layer may be formed of silicon nitride by a CVD process.

Referring to FIG. 6, a second impurity may be implanted by a second ion-implantation process to form a first source/drain region 150 at an upper portion of the stress channel layer 125 adjacent to the gate structure 140.

In some embodiments, if the stress channel layer 125 includes silicon, the second impurity may include n-type impurities. In this case, a negative metal oxide semiconductor (NMOS) transistor may be defined by the gate structure 140 and the first source/drain region 150.

In some embodiments, if the stress channel layer 125 includes SiGe, the second impurity may include p-type impurities. In this case, a positive metal oxide semiconductor (PMOS) transistor may be defined by the gate structure 140 and the first source/drain region 150.

In example embodiments, the second ion-implantation process may be performed in a high temperature condition substantially the same as or similar to that of the first ion-implantation process. The second ion-implantation process may be performed at a temperature ranging from about 100° C. to about 600° C. In some embodiments, the second ion-implantation process may be performed at a temperature ranging from about 300° C. to about 500° C.

The second ion-implantation process for the formation of the first source/drain region 150 may be performed in the high temperature condition so that a stress relaxation caused by the second impurity may be reduced or possibly prevented in the stress channel layer 125. Thus, if the stress channel layer 125 serves as a channel of the NMOS transistor, a desired tensile stress may be maintained to facilitate an electron mobility. If the stress channel layer 125 serves as a channel of the PMOS transistor, a desired compressive stress may be maintained to facilitate a hole mobility.

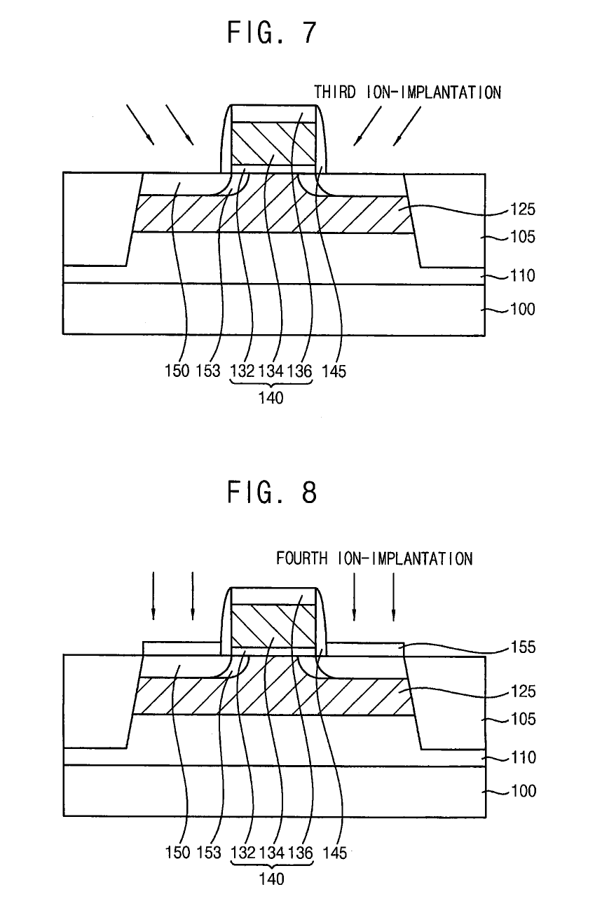

Referring to FIG. 7, a third impurity may be implanted by a third ion-implantation process to form a halo region 153 at an upper portion of the stress channel layer 125 adjacent to the first source/drain region 150 and the gate structure 140.

If the second impurity includes the n-type impurities, the third impurity may include p-type impurities. If the second impurity includes the p-type impurities, the third impurity may include n-type impurities.

The third ion-implantation process may include a halo implantation process in which impurities may be implanted by a predetermined tilting angle. A short channel caused when the first source/drain region 150 is excessively expanded may be reduced or possibly prevented by the halo region 153.

In example embodiments, the third ion-implantation process may be performed in a high temperature condition substantially the same as or similar to that of the first ion-implantation process. The third ion-implantation process may be performed at a temperature ranging from about 100° C. to about 600° C. In some embodiments, the third ion-implantation process may be performed at a temperature ranging from about 300° C. to about 500° C.

Referring to FIG. 8, a second source/drain region 155 may be formed on the first source/drain region 150.

In example embodiments, the second source/drain region 155 may be formed by a SEG process using the first source/drain region 150 as a seed layer. For example, the SEG process may be performed while providing a silicon source gas such as dichlorosilane to form an elevated source-drain (ESD) layer. In this case, the ESD layer may include silicon. Subsequently, a fourth impurity may be implanted by a fourth ion-implantation process to form a third source/drain region 155.

In example embodiments, the second source/drain region 155 may be provided as an ESD region, and the first source/drain region 150 may serve as a lightly doped drain (LDD) region.

In some embodiments, an additional stress may be applied to the stress channel layer 125 by the second source/drain region 155.

In some embodiments, while performing the SEG process, a germanium source gas may be provided together with the silicon source gas. In this case, the second source/drain region 155 may include SiGe and may contain a compressive stress.

In some embodiments, while performing the SEG process, a hydrocarbon gas such as pentyne (C₅H₅) or a heptyne (C₇H₇) may be provided together with the silicon source gas. In this case, the second source/drain region 155 may include silicon carbide (SiC), and may contain a tensile stress.

In some embodiments, while performing the SEG process, a manganese source gas may be optionally provided together with the germanium source gas. In this case, the second source/drain region 155 may include germanium or germanium-manganese (Ge—Mn).

In example embodiments, the fourth ion-implantation process may be performed in a high temperature condition substantially the same as or similar to that of the first ion-implantation process. The fourth ion-implantation process may be performed at a temperature ranging from about 100° C. to about 600° C. In some embodiments, the fourth ion-implantation process may be performed at a temperature ranging from about 300° C. to about 500° C.

In some embodiments, a second thermal treatment may be further performed so that the second source/drain region 155 and/or the first source/drain region 150 may be crystallized. The second thermal treatment may include a low temperature annealing performed at a temperature less than 1,000° C., e.g., ranging from about 500° C. to about 900° C. Thus, a stress relaxation caused by a high temperature thermal treatment may be reduced or possibly prevented.

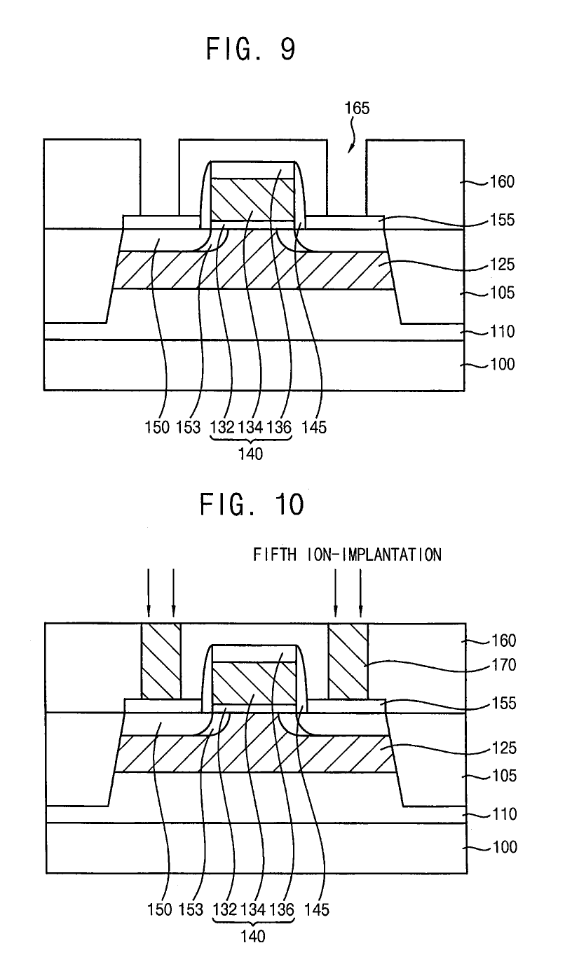

Referring to FIG. 9, an insulating interlayer 160 covering the second source/drain region 155 and the gate structure 140 may be formed on the isolation layer 105 and the stress channel layer 125. The insulating interlayer 160 may be partially etched to form a contact hole 165 through which the second source/drain region 155 may be at least partially exposed.

The insulating interlayer 160 may be formed of a silicon oxide-based material such as tetraethyl orthosilicate (TEOS), boro silicate glass (BSG), phospho silicate glass (PSG), boro phospho silicate glass (BPSG), or the like by a CVD process or a spin coating process.

Referring to FIG. 10, a contact 170 filling the contact hole 165 may be formed to be in contact with the second source/drain region 155.

In example embodiments, a preliminary contact layer sufficiently filling the contact hole 165 may be formed by a SEG process using the second source/drain region 155 as a seed layer. An upper portion of the preliminary contact layer may be planarized by a CMP process until an upper surface of the insulating interlayer 160 is exposed to form a preliminary contact. A fifth impurity may be implanted into the preliminary contact by a fifth ion-implantation process to form a contact 170.

In some embodiments, the preliminary contact layer may be formed by depositing polysilicon or amorphous silicon by, e.g., an ALD process, a PVD process, a CVD process, etc.

In example embodiments, the fifth ion-implantation process may be performed in a high temperature condition substantially the same as or similar to that of the first ion-implantation process. The fifth ion-implantation process may be performed at a temperature ranging from about 100° C. to about 600° C. In some embodiments, the fifth ion-implantation process may be performed at a temperature ranging from about 300° C. to about 500° C.

Additionally, a third thermal treatment including a low temperature annealing may be performed so that the contact 170 may be crystallized.

A wiring structure and an additional insulating interlayer may be further formed on the contact 170.

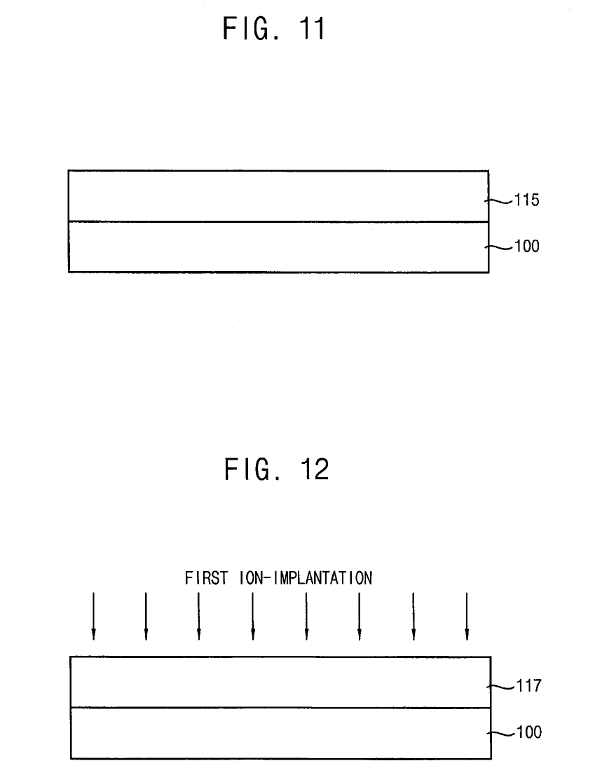

FIGS. 11 to 15 are cross-sectional views illustrating a method of manufacturing a semiconductor device in accordance with some example embodiments. Detailed descriptions on processes and/or materials substantially the same as or similar to those illustrated with reference to FIGS. 1 to 10 are omitted herein, and like reference numerals are used to designate like elements.

Referring to FIG. 11, a preliminary stress relaxation buffer (SRB) layer 115 may be formed on a semiconductor substrate 100. The preliminary SRB layer 115 may be formed from materials and processes substantially the same as or similar to the SRB layer 110 illustrated with reference to FIG. 1.

Referring to FIG. 12, a first ion-implantation process may be performed on the preliminary SRB layer 115. Accordingly, a first impurity may be implanted such that the preliminary SRB layer 115 may be converted into an SRB layer 117.

The first ion-implantation process may be performed in a condition substantially the same as or similar to those of the ion-implantation processes illustrated with reference to FIGS. 1 to 10. For example, the first ion-implantation process may be performed at a temperature ranging from about 100° C. to about 600° C. In some embodiments, the first ion-implantation process may be performed at a temperature ranging from about 300° C. to about 500° C.

The first ion-implantation process may be performed in a relatively high temperature condition, so that a stress relaxation caused by, e.g., a Si—Ge bond damage included in the preliminary SRB layer 115 and/or the SRB layer 117 may be reduced or possibly prevented. Further, the first ion-implantation process may have an effect substantially the same as or similar to that of a soft-annealing. Thus, defects in the preliminary SRB layer 115 may be cured by the first ion-implantation process.

In some embodiments, a cleaning process may be further performed on the SRB layer 117. A native oxide layer that may be formed on the SRB layer 117 during the first ion-implantation process may be removed.

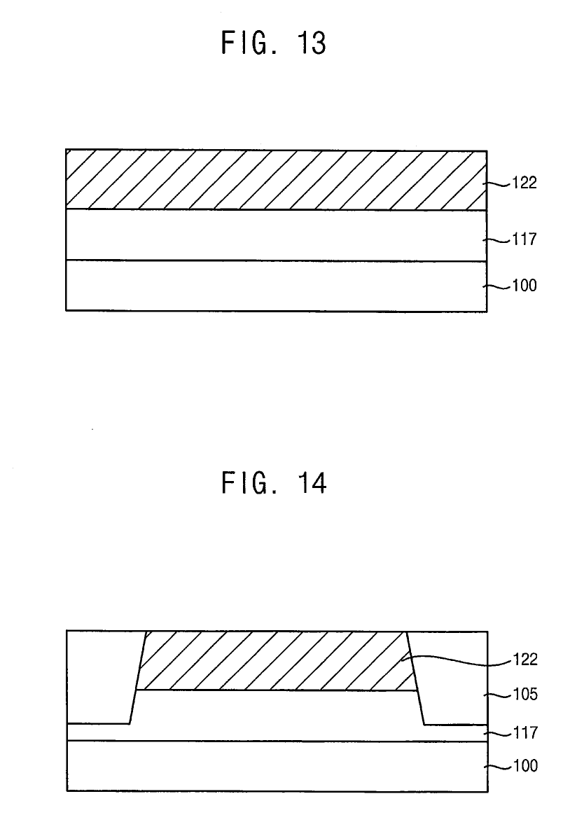

Referring to FIG. 13, a stress channel layer 122 may be formed on the SRB layer 117.

The stress channel layer 122 may be formed by a SEG process using the SRB layer 117 as a seed layer. In example embodiments, the stress channel layer 122 may include Si, Si—Ge or Ge.

In example embodiments, the SRB layer 117 and the stress channel layer 122 may be formed by an ex-situ process.

In some embodiments, a second ion-implantation process may be performed on the stress channel layer 122. The second ion-implantation process may be performed in a high temperature condition substantially the same as or similar to that of the first ion-implantation processes. For example, the second ion-implantation process may be performed at a temperature ranging from about 100° C. to about 600° C. In some embodiments, the second ion-implantation process may be performed at a temperature ranging from about 300° C. to about 500° C.

Referring to FIG. 14, an isolation layer 105 may be formed by a process substantially the same as or similar to that illustrated with reference to FIG. 2.

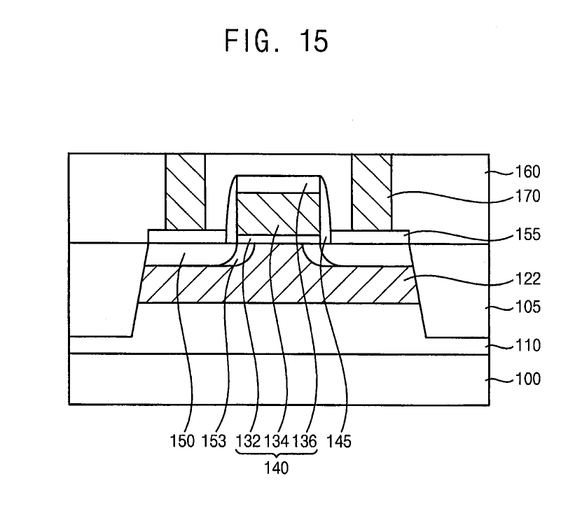

Referring to FIG. 15, processes substantially the same as or similar to those illustrated with reference to FIGS. 4 to 10 may be performed.

In example embodiments, a gate structure 140 and a gate spacer 145 may be formed on the stress channel layer 122, and a first source/drain region 150 and a halo region 153 may be formed at upper portions of the stress channel layer 122 adjacent to the gate structure 140. Accordingly, an NMOS transistor or a PMOS transistor may be defined on the stress channel layer 122.

A second source/drain region 155 may be formed on the first source/drain region 150, and a contact 170 electrically connected to the second source/drain region 155 may be formed through an insulating interlayer 160.

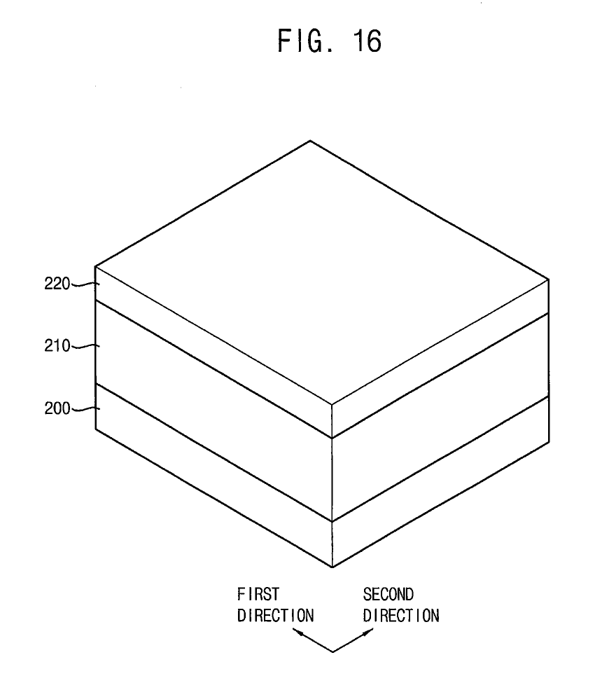

FIGS. 16 to 29 are perspective views and cross-sectional views illustrating a method of manufacturing a semiconductor device in accordance with example embodiments. For example, FIGS. 16 to 29 illustrate a method of manufacturing a semiconductor device including a fin field-effect transistor (FinFET).

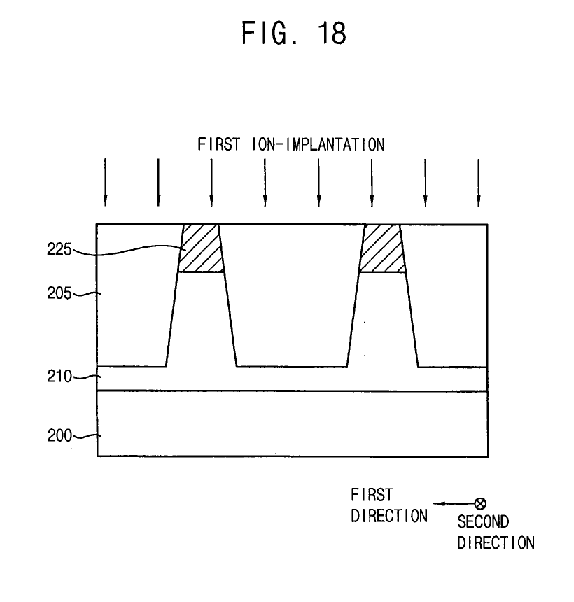

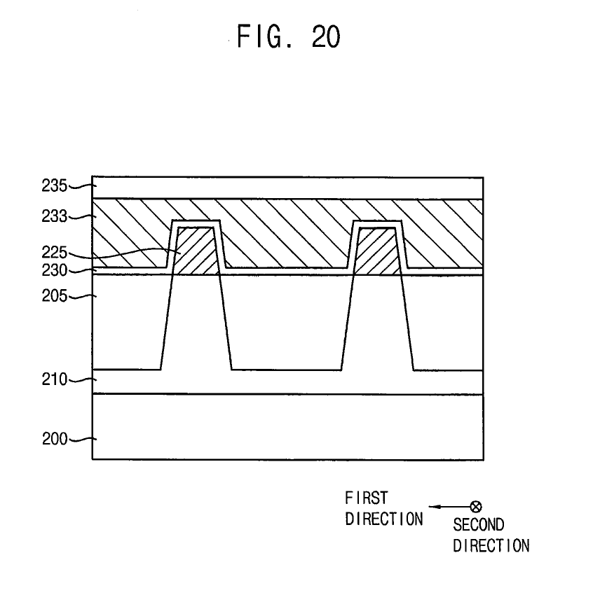

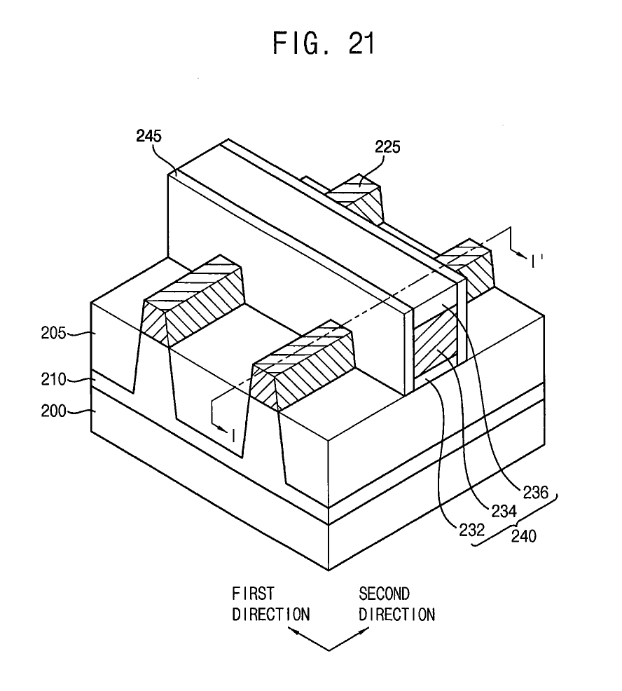

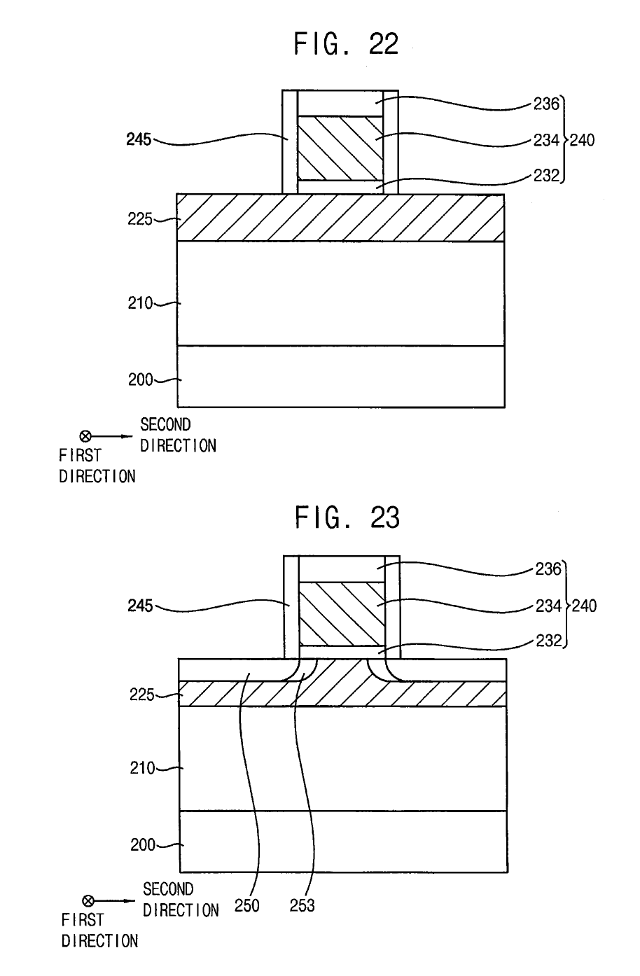

Specifically, FIGS. 16, 17, 19, 21, 24, 26 and 27 are perspective views illustrating the method. FIGS. 18 and 20 are cross-sectional views taken along a first direction. FIGS. 22, 23, 25, 28 and 29 are cross-sectional views taken along the line I-I′ indicated in FIGS. 21, 24 and 27.

Two directions substantially parallel to an upper surface of a semiconductor substrate and perpendicular to each other are defined as a first direction and a second direction in FIGS. 16 to 29. The direction indicated by an arrow and a reverse direction thereof are considered as the same direction.

Detailed descriptions on processes and/or materials substantially the same as or similar to those illustrated with reference to FIGS. 1 to 10 are omitted herein.

Referring to FIG. 16, a process substantially the same as or similar to that illustrated with reference to FIG. 1 may be performed.

In example embodiments, an SRB layer 210 and a preliminary stress channel layer 22Q may be sequentially formed on a semiconductor substrate 200.

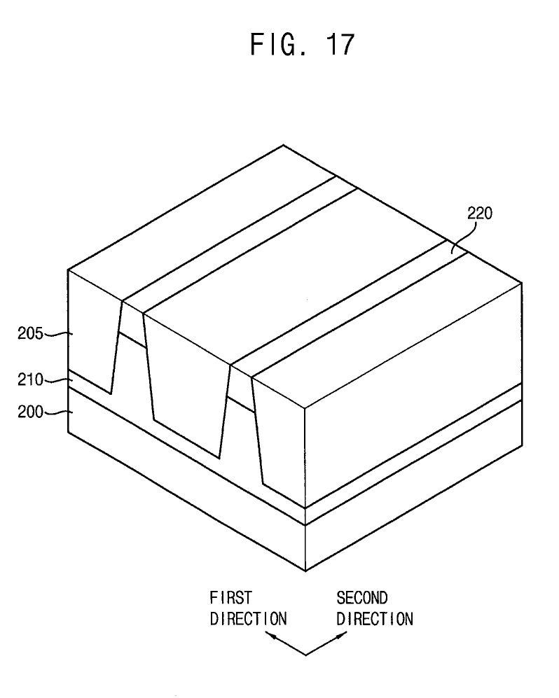

Referring to FIG. 17, a process substantially the same as or similar to that illustrated with reference to FIG. 2 may be performed to form an isolation layer 205 (e.g., an STI last process). A region on the semiconductor substrate 200 may be divided into an active region and a field region by the isolation layer 205.

Referring to FIG. 17, a process substantially the same as or similar to that illustrated with reference to FIG. 3 may be performed. Accordingly, a first ion-implantation process may be performed such that the preliminary stress channel layer 220 may be converted into a stress channel layer 225.

As described above, the first ion-implantation process may be performed at a temperature ranging from about 100° C. to about 600° C. In some embodiments, the first ion-implantation process may be performed at a temperature ranging from about 300° C. to about 500° C.

As illustrated in FIGS. 16 to 18, the preliminary stress channel layer 220 may be formed, and then the stress channel layer 225 may be formed by the first ion-implantation process. In this case, the SRB layer 210 and the stress channel layer 225 may be formed by an in-situ process.

In some embodiments, as illustrated with reference to FIGS. 11 to 14, a preliminary SRB layer may be formed on the semiconductor substrate 200, and the first ion-implantation process may be performed such that the preliminary SRB layer may be converted into an SRB layer. A stress channel layer may be formed on the SRB layer, and then an isolation layer may be formed. In this case, the SRB layer and the stress channel layer may be formed by an ex-situ process. An additional ion-implantation process may be performed on the stress channel layer.

In some embodiments, as illustrated with reference to FIG. 4, a low temperature annealing may be performed selectively on the stress channel layer 225 at a temperature less than about 1,000° C. In some embodiments, the low temperature annealing may be performed at a temperature ranging from about 500° C. to about 900° C.

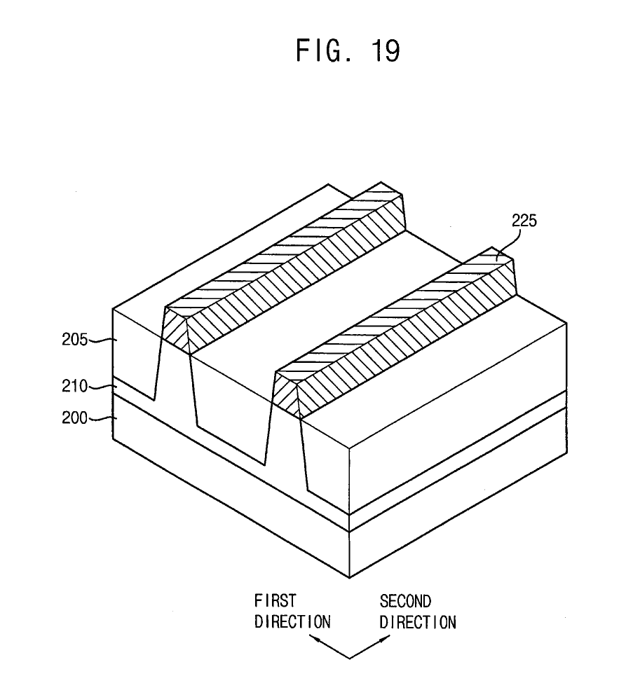

Referring to FIG. 19, an upper portion of the isolation layer 205 may be removed by, e.g., an etch-back process such that the stress channel layer 225 may be exposed. The exposed stress channel layer 225 may be defined as a semiconductor fin. The semiconductor fin may extend in the second direction, and a plurality of the semiconductor find may be arranged along the first direction.

As illustrated in FIG. 19, the stress channel layer 225 may be entirely exposed by the etch-back process. In some embodiments, an upper portion of the stress channel layer 225 may be partially exposed by the etch-back process.

Referring to FIG. 20, a gate insulation layer 230 covering the stress channel layer 225 may be formed on the isolation layer. A gate electrode layer 233 and a gate mask layer 235 may be sequentially formed on the gate insulation layer 230.

The gate insulation layer 230 may be conformally deposited along an upper surface of the isolation layer 205 and surfaces of the stress channel layer 225. In some embodiments, the gate insulation layer 230 may be formed by a thermal oxidation of the surfaces of the stress channel layer 225. In this case, the gate insulation layer 230 may be formed as an individual pattern on each stress channel layer 225 separated by the isolation layer 205.

Referring to FIGS. 21 and 22, the gate mask layer 235 may be patterned to form a gate mask 236 extending in the first direction. The gate electrode layer 233 and the gate insulation layer 230 may be partially removed using the gate mask 236 as an etching mask to form a gate electrode 234 and a gate insulation layer pattern 232.

Accordingly, a gate structure 240 including the gate insulation layer pattern 232, the gate electrode 234 and the gate mask 236 sequentially stacked on the isolation layer 205 or the stress channel layer 225, and extending in the first direction may be formed. The gate structure 240 may overlie a plurality of the stress channel layers 225 protruding from the upper surface of the isolation layer 205.

FIGS. 21 and 22 illustrate only one gate structure 240, however, a plurality of the gate structures 240 may be formed along the second direction.

Further, a gate spacer 245 may be formed on a sidewall of the gate structure 240.

Referring to FIG. 23, processes substantially the same as or similar to those illustrated with reference to FIGS. 6 and 7 may be performed.

In example embodiments, a second ion-implantation process may be performed using the gate structure 240 as an implantation mask to form a first source/drain region 250. Accordingly, a FinFET may be defined by the stress channel layer 225 serving as the semiconductor fin, the gate structure 240 and the first source/drain region 250. The first source-drain region 25Q may serve as, e.g., an LDD region.

A third ion-implantation process in which impurities may be implanted by a predetermined tilting angle may be performed to form a halo region 253.

The second and third ion-implantation processes may be performed in a condition substantially the same as or similar to that of the first ion-implantation process. The second and third ion-implantation processes may be performed at a temperature ranging from about 100° C. to about 600° C., in some embodiments, from about 300° C. to about 500° C.

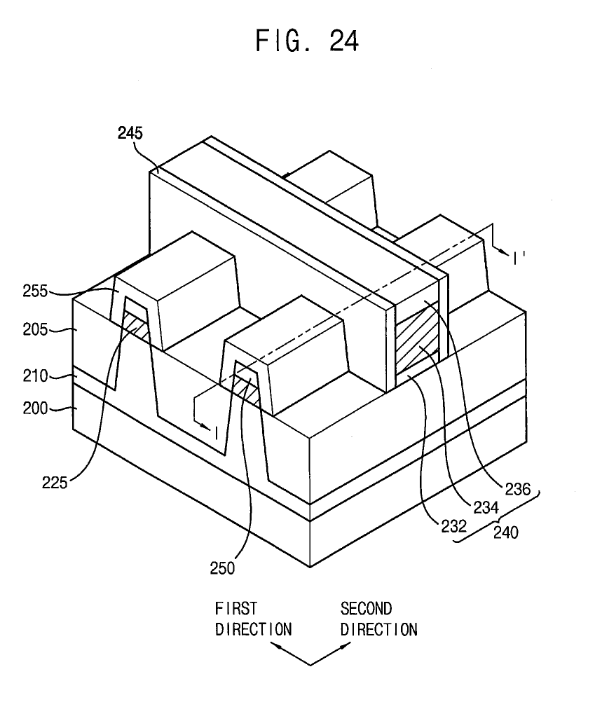

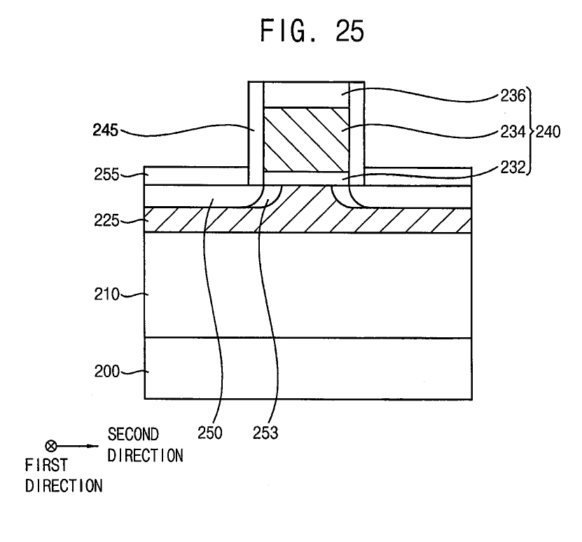

Referring to FIGS. 24 and 25, a process substantially the same as or similar to that illustrated with reference to FIG. 8 may be performed.

For example, an ESD layer may be formed by a SEG process using the stress channel layer 225 and/or the first source/drain region 250 as a seed layer, and then a fourth ion-implantation process may be performed on the ESD layer to form a second source/drain region 255. The fourth ion-implantation process may be also performed at a high temperature ranging from about 100° C. to about 600° C., in some embodiments, from about 300° C. to about 500° C.

The second source/drain region 255 may include a compressive semiconductor material such as Si—Ge, Ge or Ge—Mn, or a tensile semiconductor material such as Si or SiC.

In some embodiments, the second source/drain region 255 may be grown uniformly from the surface of the stress channel layer 225. In this case, as illustrated in FIG. 24, the second source/drain region 255 may have a trapezoidal or rectangular cross-sectional shape.

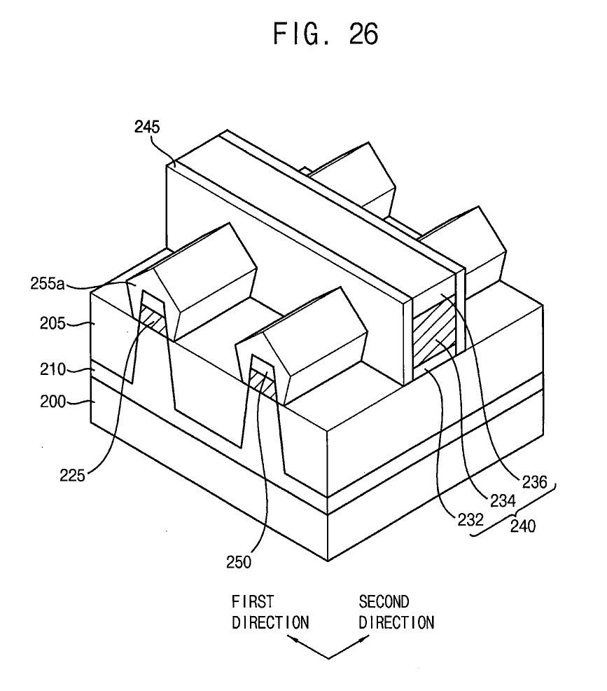

In some embodiments, as illustrated in FIG. 26, a second source/drain region 255a may be grown ununiformly from the surface of the stress channel layer 225. In this case, the second source/drain region 255a may have various cross-sectional shapes, e.g., a rhombus shape, a pentagonal shape or a hexagonal shape.

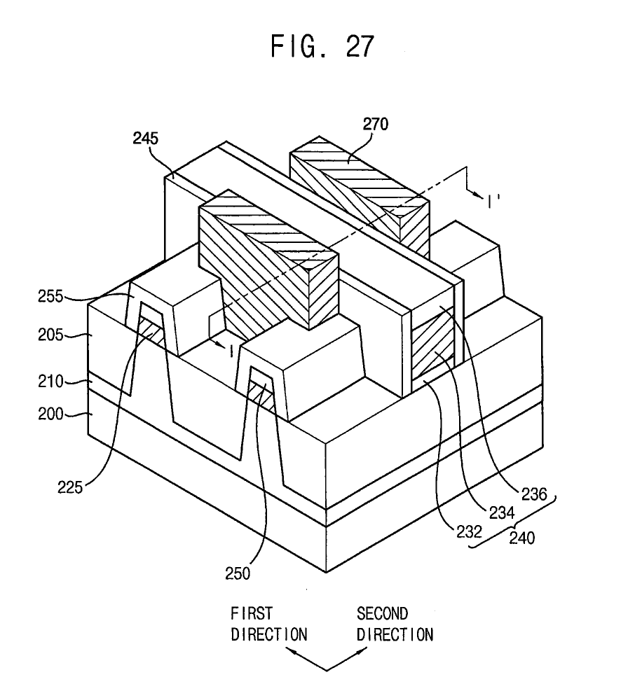

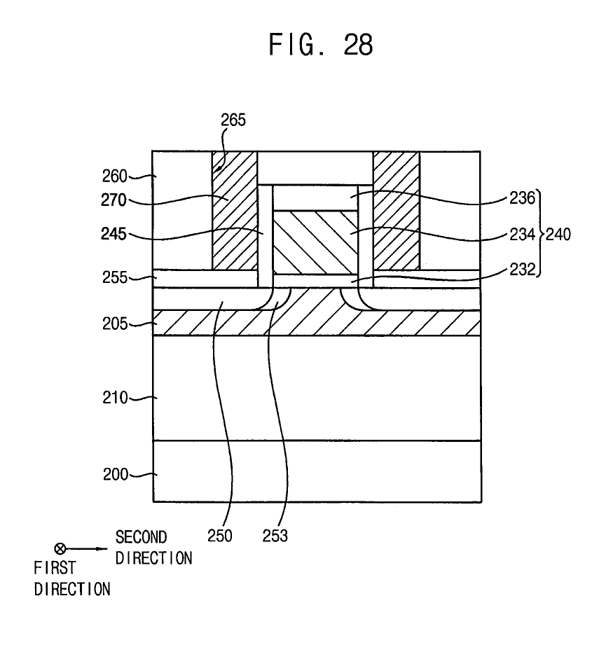

Referring to FIGS. 27 and 28, processes substantially the same as or similar to those illustrated with reference to FIGS. 9 and 10 may be performed.

In example embodiments, an insulating interlayer 260 covering the second source/drain region 255, the gate spacer 245 and the gate structure 240 may be formed on the isolation layer 205. For convenience of descriptions, an illustration of the insulating interlayer 260 is omitted in FIG. 27.

The insulating interlayer 260 may be partially removed to form a contact hole 265 through which the second source/drain region 255 may be at least partially exposed. A preliminary contact layer filling the contact hole 265 may be formed by a SEG process using the second source/drain region 255 as a seed layer. A fifth ion-implantation process may be performed on the preliminary contact layer to form the contact 270 filling the contact hole 265 and contacting the second source/drain region 255.

In some embodiments, the preliminary contact layer may be formed by depositing polysilicon or amorphous silicon through, e.g., an ALD process, a PVD process, a CVD process, or the like.

The fifth ion-implantation process may be performed at a high temperature ranging from about 100° C. to about 600° C., in some embodiments, from about 300° C. to about 500° C. Further, a low temperature annealing may be performed at a temperature ranging from about 500° C. to about 900° C. so that the contact 270 may be crystallized.

In some embodiments, a plurality of the second source/drain regions 255 may be exposed through the contact hole 265. For example, two second source/drain regions 255 neighboring in the first direction may be exposed through one contact hole 265. In this case, as illustrated in FIG. 27, the one contact 270 may be in contact with the two second source/drain regions 255. Thus, an alignment tolerance for the formation of the contact 270 may be increased.

The second source/drain region 255 may be expanded from the stress channel layer 225 serving as the semiconductor fin, and may serve as a pad on which the contact 270 may be landed. The alignment tolerance may be further increased by an expanded width of the second source/drain region 255.

The gate spacer 245 may serve as a self-alignment pattern or a guide pattern for the formation of the contact 270 and/or the contact hole 265. In this case, the contact 270 may be in contact with a sidewall of the gate spacer 245, and the alignment tolerance may be also increased by the gate spacer 245.

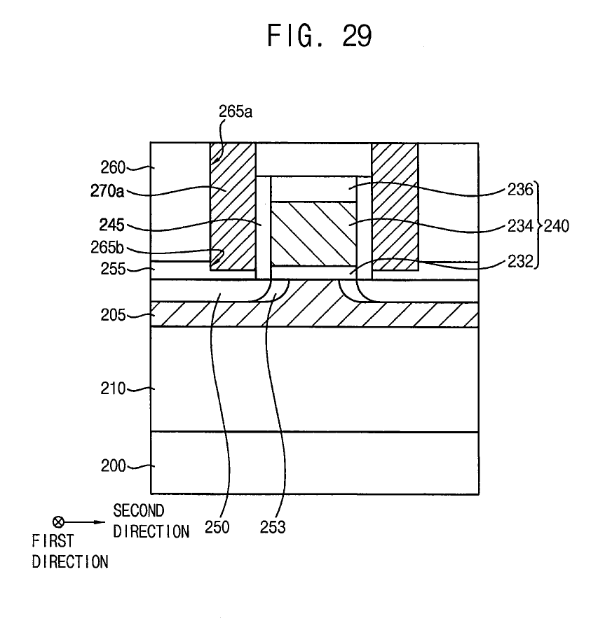

In some embodiments, as illustrated in FIG. 29, an upper portion of the second source/drain region 255 may be partially removed while forming a contact hole 265a such that a recess 265b may be formed. In this case, the contact 270a may extend through the insulating interlayer 260 and may be inserted in the recess 265b.

A seed area of the SEG process for the formation of the contact 270a may be increased by the recess 265b. Thus, defects in the contact 270a may be reduced. Additionally, an electrical distance between the contact 265a and the first source/drain region 250 may be reduced so that operational properties of the FinFET may be improved.

FIGS. 30 to 34 are cross-sectional views illustrating a method of manufacturing a semiconductor device in accordance with some example embodiments. For example, FIGS. 30 to 34 illustrate a method of manufacturing a semiconductor device including a FinFET.

Detailed descriptions on processes and/or materials substantially the same as or similar to those illustrated with reference to FIGS. 1 to 10, or FIGS. 16 to 29 may be omitted herein. The definitions of directions are substantially the same as those in FIGS. 16 to 29.

Referring to FIG. 30, an SRB layer 212 may be formed on a semiconductor substrate 200, and an isolation layer 205 may be formed to define an active region.

For example, a trench 202 may be formed by an STI process, and the isolation layer 205 filling the trench 202 may be formed. As illustrated in FIG. 30, the trench 202 may be formed through the SRB layer 212 and may extend to an upper portion of the semiconductor substrate 200. In some embodiments, the trench 202 may be formed in the SRB layer 212, and may not extend to the semiconductor substrate 200. In some embodiments, an upper surface of the semiconductor substrate 200 may be exposed through the trench 202.

Referring to FIG. 31, an upper portion of the SRB layer 212 may be removed by, e.g., an etch-back process. Accordingly, a first recess 207 may be defined at a space from which the upper portion of the SRB layer 212 is removed.

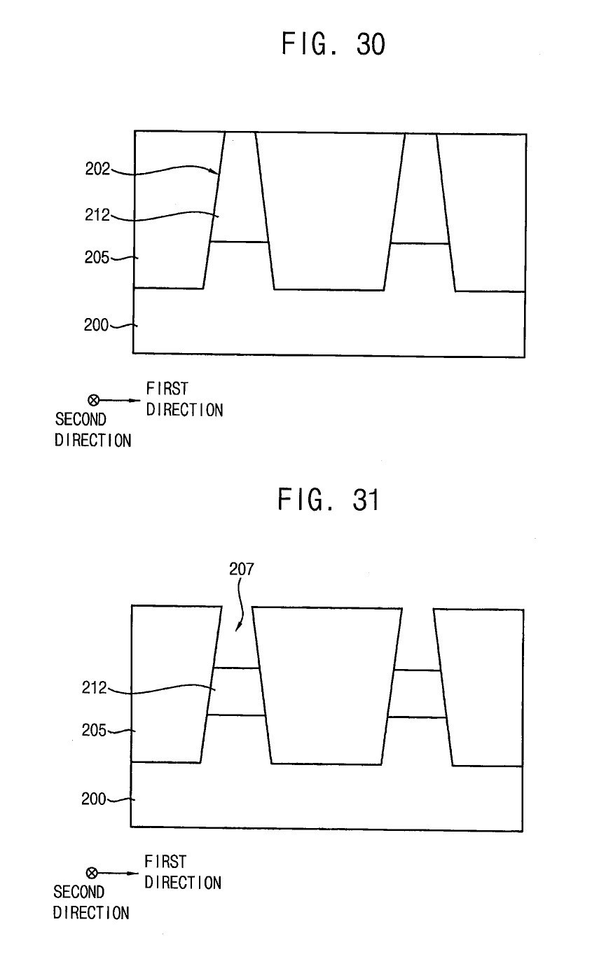

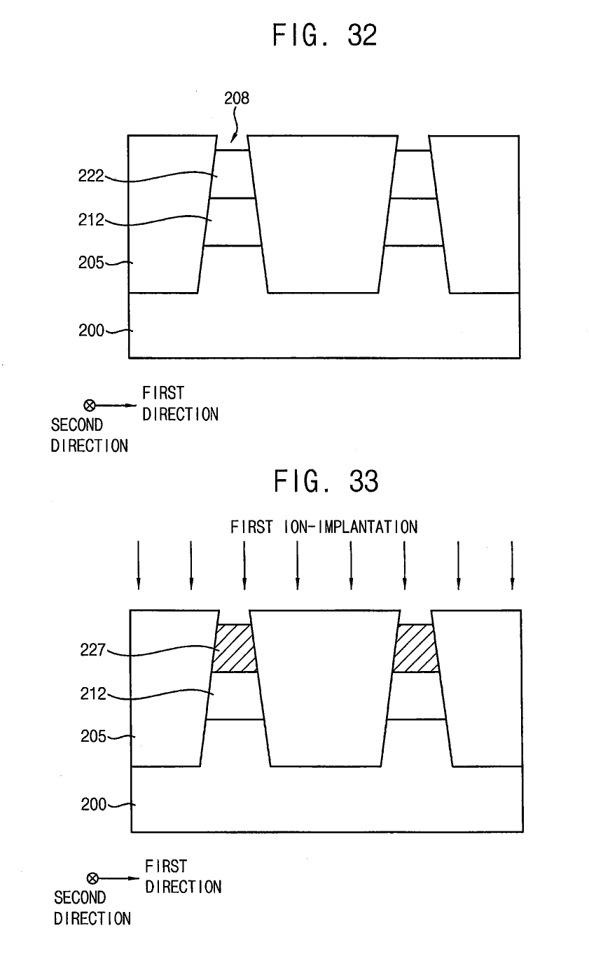

Referring to FIG. 32, a preliminary stress channel layer 222 at least partially filling the first recess 207 may be formed.

In example embodiments, the preliminary stress channel layer 222 may be formed by a SEG process using an upper surface of the SRB layer 212 exposed through the first recess 207 as a seed layer. As described with reference to FIG. 1, the preliminary stress channel layer 222 may include tensile silicon, Si—Ge or Ge.

As illustrated in FIG. 32, the preliminary stress channel layer 222 may partially fill the first recess 207. Accordingly, a second recess 208 may be defined by a sidewall of the isolation layer 205 and an upper surface of the preliminary stress channel layer 222.

In some embodiments, the preliminary stress channel layer 222 may substantially and fully fill the first recess 207.

Referring to FIG. 33, a process substantially the same as or similar to that illustrated with reference to FIG. 3 or FIG. 18 may be performed. In example embodiments, a first ion-implantation process may be performed such that the preliminary stress channel layer 222 may be converted into a stress channel layer 227.

In example embodiments, the first ion-implantation process may be performed at a high temperature ranging from about 100° C. to about 600° C., in some embodiments, from about 300° C. to about 500° C.

The second recess 208 may serve as a guide for a first impurity while performing the first ion-implantation process. Thus, a doping efficiency into the preliminary stress channel layer 222 may be improved.

In some embodiments, as illustrated with reference to FIGS. 11 to 14, a preliminary SRB layer may be formed on the semiconductor substrate 200. The first recess 207 may be formed, and then a first ion-implantation process may be performed such that the preliminary SRB layer may be converted into an SRB layer. A stress channel layer filling the first recess 207 may be formed on the SRB layer. Subsequently, an additional ion-implantation process may be performed selectively on the stress channel layer.

In some embodiments, as illustrated with reference to FIG. 4, a low temperature annealing may be performed on the stress channel layer 227 at a temperature less than about 1,000° C. In some embodiments, the low temperature annealing may be performed at a temperature ranging from about 500° C. to about 900° C.

Referring to FIG. 34, a process substantially the same as or similar to that illustrated with reference to FIG. 19 may be performed.

For example, the isolation layer 205 may be additionally removed by an etch-back process such that the stress channel layer 227 may be at least partially exposed to define a semiconductor fin.

Subsequently, process substantially the same as or similar to those illustrated with reference to FIGS. 20 to 29 may be performed to obtain the semiconductor device including the FinFET.

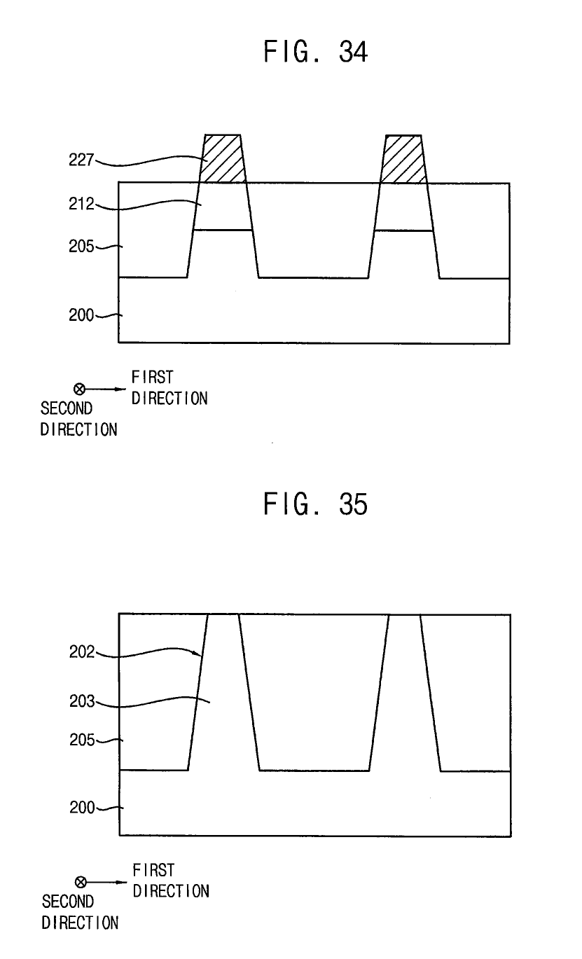

FIGS. 35 to 40 are cross-sectional views illustrating a method of manufacturing a semiconductor device in accordance with some example embodiments. For example, FIGS. 35 to 40 illustrate a method of manufacturing a semiconductor device including a FinFET.

Detailed descriptions on processes and/or materials substantially the same as or similar to those illustrated with reference to FIGS. 1 to 10, FIGS. 16 to 29, or FIGS. 30 to 34 may be omitted herein. The definitions of directions are substantially the same as those in FIGS. 16 to 29.

Referring to FIG. 35, an isolation layer 205 may be formed on a semiconductor substrate 200 to define an active region. For example, an STI process (e.g., an STI first process) may be performed to form a trench 202 at an upper portion of the semiconductor substrate 200, and an isolation layer 205 filling the trench 202 may be formed.

After the formation of the isolation layer 205, a dummy active pattern 203 protruding from an upper surface of the semiconductor substrate 200 or a bottom of the isolation layer 205 may be defined. The dummy active pattern 203 may extend in the second direction, and a plurality of the dummy active patterns 203 may be formed long the first direction.

Referring to FIG. 36, the dummy active pattern 203 may be removed. A first recess 207a may be defined at a space from which the dummy active pattern 203 is removed.

In example embodiments, the dummy active pattern 203 may be removed by an etch-back process, or an etching process using an etchant solution or an etching gas that may include hydrogen chloride (HCl).

The first recess 207a may be defined by a sidewall of the isolation layer 205 and the upper surface of the semiconductor substrate 200. In some embodiments, the bottom of the isolation layer 205 and the upper surface of the semiconductor substrate 200 may be coplanar.

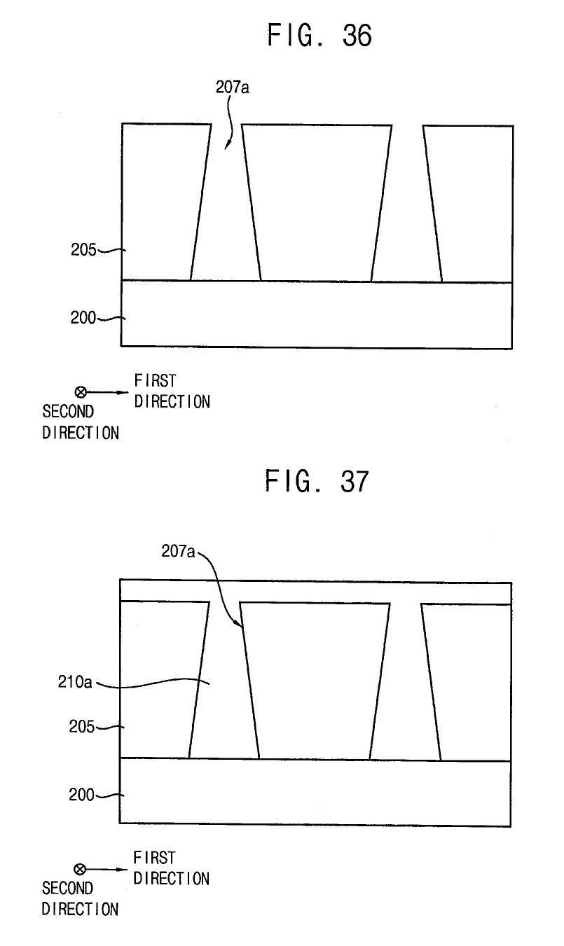

Referring to FIG. 37, an SRB layer 210a filling the first recess 207a may be formed on the semiconductor substrate 200.

As described with reference to FIG. 1, the SRB layer 210a may be formed by a SEG process using the upper surface of the semiconductor substrate 200 as a seed layer. In some embodiments, the SRB layer 210a may sufficiently fill the first recess 207a, and may cover an upper surface of the isolation layer 205.

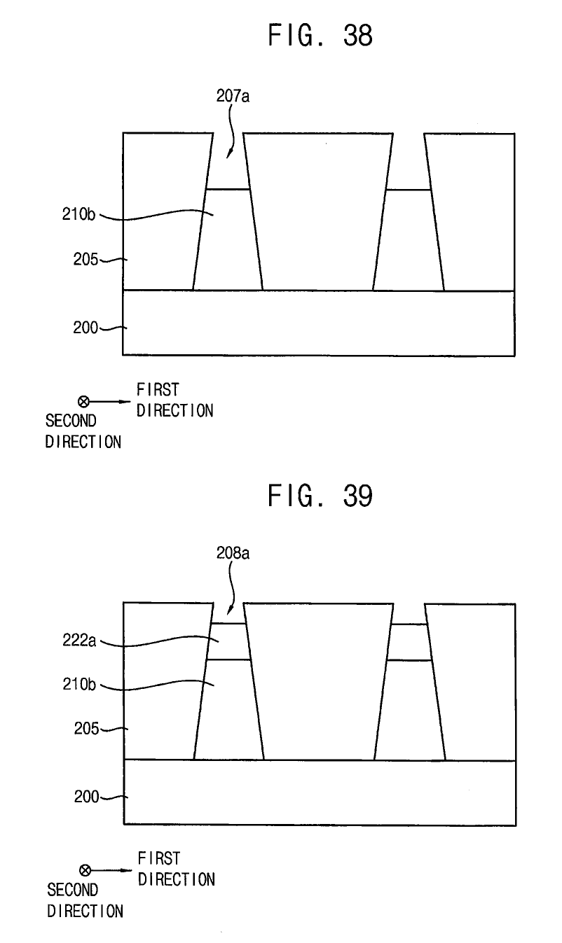

Referring to FIG. 38, an upper portion of the SRB layer 210a may be removed to form an SRB layer pattern 210b.

In example embodiments, the SRB layer 210a may be planarized by a CMP process until the upper surface of the isolation layer 205 is exposed. An upper portion of the remaining SRB layer 210a may be removed by an etch-back process or an etching process using HCl. Accordingly, the SRB layer pattern 210b partially filling the first recess 207a may be formed.

The SRB layer pattern 210b may be formed in each first recess 207a, and may extend linearly in the second direction.

Referring to FIG. 39, a process substantially the same as or similar to that illustrated with reference to FIG. 32 may be performed to form a preliminary stress channel layer 222a.

In some embodiments, as illustrated in FIG. 39, the preliminary stress channel layer 222a may be grown from the SRB layer pattern 210b to partially fill the first recess 207a. Accordingly, a second recess 208a may be defined by the sidewall of the isolation layer 205 and an upper surface of the preliminary stress channel layer 222a.

In some embodiments, the preliminary channel layer 222a may substantially and fully fill the first recess 207a.

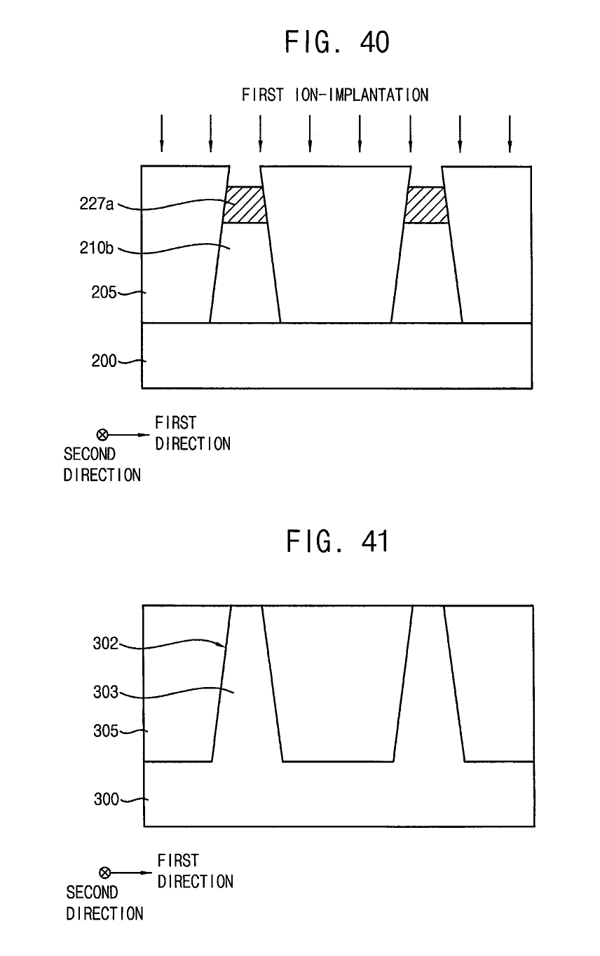

Referring to FIG. 40, as also illustrated with reference to FIG. 33, the preliminary stress channel layer 222a may be converted into a stress channel layer 227a by a first ion-implantation process.

In some embodiments, the formation of the SRB layer 210a may be omitted, and a preliminary stress channel layer may be formed directly from the upper surface of the semiconductor substrate 200 to fill the first recess 207a. Subsequently, a first ion-implantation process may be performed such that the preliminary stress channel layer may be converted into a stress channel layer. In this case, a time and/or a temperature for the first ion-implantation process may be increased so that defects or cracks that may be included in the preliminary stress channel layer may be cured.

In some embodiments, the first ion-implantation process may be performed after the formation of the SRB layer pattern 210b, and then a stress channel layer may be formed on the SRB layer pattern 210b. An additional ion-implantation process may be further performed on the stress channel layer.

In some embodiments, as illustrated with reference to FIG. 4, a low temperature annealing may be performed on the stress channel layer 227a at a temperature less than about 1,000° C. In some embodiments, the low temperature annealing may be performed at a temperature ranging from about 500° C. to about 900° C.

Subsequently, as also illustrated with reference to FIGS. 19 to 34, an upper portion of the isolation layer 205 may be removed such that the stress channel layer 227a may be at least partially exposed to form a semiconductor fin. Additionally, processes substantially the same as or similar to those illustrated with reference to FIGS. 20 to 29 may be performed to achieve the semiconductor device including the FinFET.

FIGS. 41 to 45 are cross-sectional views and perspective views illustrating a method of manufacturing a semiconductor device in accordance with some example embodiments. For example, FIGS. 41 to 45 illustrate a method of manufacturing a FinFET device including a group III-V channel.

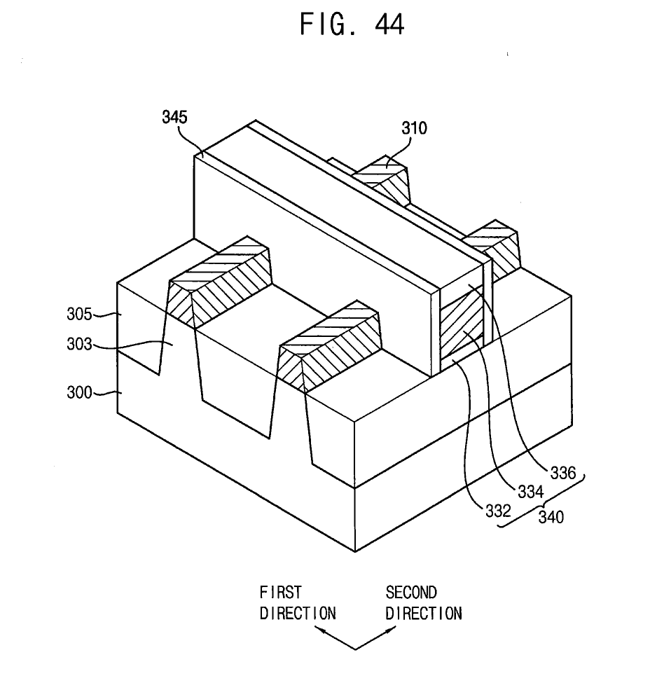

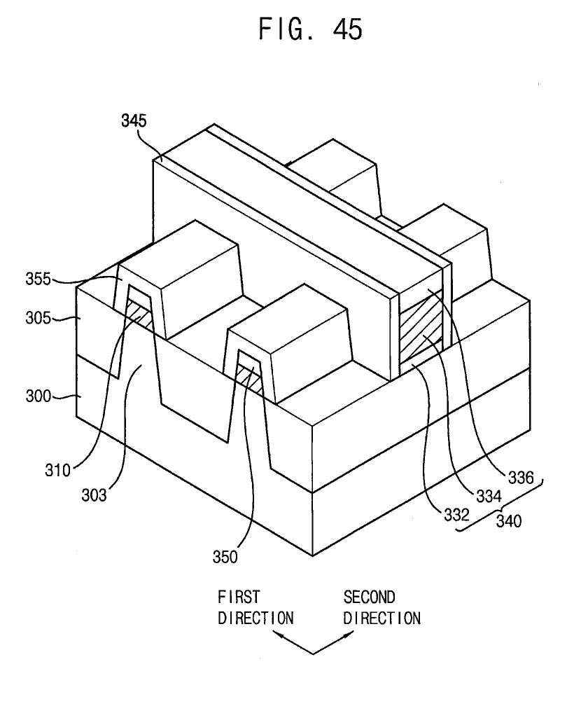

Specifically, FIGS. 41 to 43 are cross-sectional views illustrating the method, and FIGS. 44 and 45 are perspective views illustrating the method.

Detailed descriptions on processes and/or materials substantially the same as or similar to those illustrated with reference to FIGS. 1 to 10, FIGS. 16 to 29, FIGS. 30 to 34 and FIGS. 35 to 40 are omitted herein. The definitions of directions are substantially the same as those in FIGS. 16 to 29.

Referring to FIG. 41, an isolation layer 305 may be formed on a semiconductor substrate 300 to define an active region. For example, an STI process may be performed to form a trench 302 at an upper portion of the semiconductor substrate 300, and the isolation layer 305 filling the trench 302 may be formed.

In example embodiments, the semiconductor substrate 300 may include a group III-V compound such as InP, GaP, GaAs or GaSb.

After the formation of the isolation layer 305, an active pattern 303 protruding from a bottom of the isolation layer 305 or an upper surface of the semiconductor substrate 300 may be formed. The active pattern 303 may extend in the second direction, and a plurality of the active patterns 303 may be formed along the first direction.

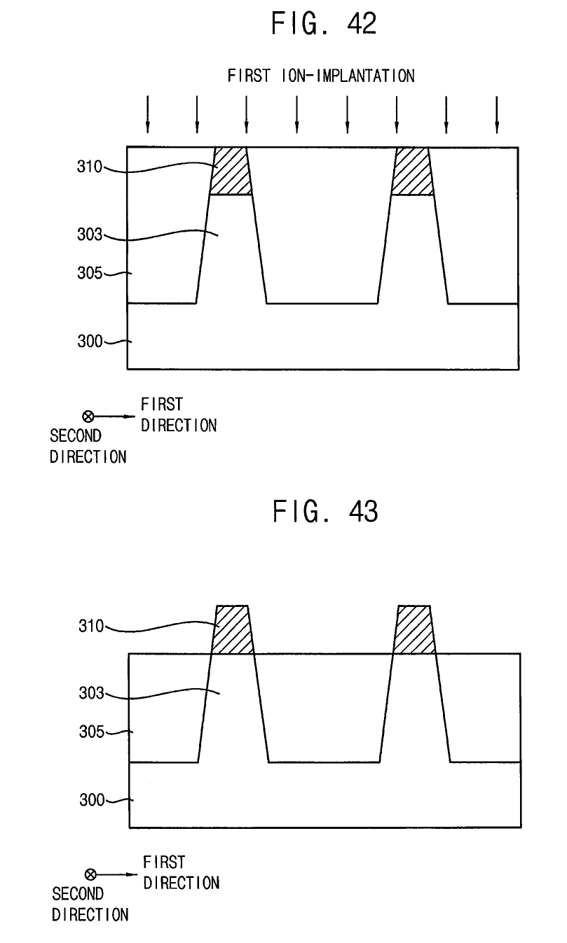

Referring to FIG. 42, a first ion-implantation process substantially the same as or similar to that illustrated with reference to FIG. 33 may be performed. Accordingly, an upper portion of the active pattern 303 may be converted into a semiconductor fin 310.

In some embodiments, p-type impurities may be implanted through the first ion-implantation process. In this case, the semiconductor fin may include a compound such as InGaAs.

As described above, the first ion-implantation process may be performed at a high temperature ranging from about 100° C. to about 600° C., in some embodiments, from about 300° C. to about 500° C.

Referring to FIG. 43, an upper portion of the isolation layer 305 may be removed by, e.g., an etch-back process such that the semiconductor fin 310 may be exposed.

Referring to FIG. 44, processes substantially the same as or similar to those illustrated with reference to FIGS. 20 to 22 may be performed.

In example embodiments, a gate structure 340 including a gate insulation layer pattern 332, a gate electrode 334 and a gate mask 336 sequentially stacked on the isolation layer 305 or the semiconductor fin 310, and extending in the first direction may be formed. The gate structure 340 may overlie a plurality of the semiconductor fins 31Q on the isolation layer 305. A gate spacer 345 may be further formed on a sidewall of the gate structure 340.

Referring to FIG. 45, processes substantially the same as or similar to those illustrated with reference to FIGS. 23 to 25 may be performed

In example embodiments, a second ion-implantation process may be performed using the gate structure 340 as an ion-implantation mask to form a first source/drain region 350 at an upper portion of the semiconductor fin 310. In some embodiments, a third ion-implantation process may be further performed to form a halo region at an upper portion of the semiconductor fin 310 adjacent to the first source/drain region 350 and the gate structure 340.

An ESD layer may be formed by a SEG process using the semiconductor fin 310 and/or the first source/drain region 35Q as a seed layer. A fourth ion-implantation process may be performed on the ESD layer to form a second source/drain region 355.

The second to fourth ion-implantation processes may be also performed at a temperature ranging from about 100° C. to about 600° C., in some embodiments, from about 300° C. to about 500° C.

Processes substantially the same as or similar to those illustrated with reference to FIGS. 27 to 29 may be further performed to form a contact electrically connected to the second source/drain region 355.

Hereinafter, example embodiments of the present inventive concept will be described with reference to Experimental Examples. However, Experimental Examples are provided only for illustration, and are not to be construed as limiting the present inventive concept.

### Evaluations on a Stress Relaxation According to an Ion-Implantation Temperature

### Experimental Example 1

### Ep 1

A Si—Ge layer having a Ge content of about 30 wt % was grown on a silicon substrate. An initial compressive stress applied to the Si—Ge layer was measured. Arsenic (As) was implanted into the Si—Ge layer at a room temperature (RT), and then a compressive stress was measured. A stress relaxation ratio (SR %) was calculated from the compressive stress measured after the ion-implantation process and the initial compressive stress (Comparative Example 1 (Com 1)). Further, an annealing process was performed at a temperature of about 1,000° C. after the ion-implantation process, and then the SR % was calculated again (Comparative Example 2 (Com 2)).

An SR % was calculated in a condition substantially the same as that of Comparative Example 1 except that a temperature of the ion-implantation process was adjusted to about 500° C. (Example 1 (Ex 1)). Further, an annealing process was performed at a temperature of about 1,000° C. after the ion-implantation process, and then the SR % was calculated again (Example 2 (Ex 2)).

### Experimental Example 2

### Ep 2

A Si—Ge layer having a Ge content of about 44 wt % was grown on a silicon substrate. An initial compressive stress applied to the Si—Ge layer was measured. Arsenic (As) was implanted into the Si—Ge layer at a room temperature, and then an annealing process was performed at a temperature of about 1,000° C. A compressive stress was measured after the annealing process, and an SR % was calculated (Comparative Example 3 (Com 3)).

An SR % was calculated in a condition substantially the same as that of Comparative Example 3 except that a temperature of the ion-implantation process was adjusted to about 500° C. (Example 3 (Ex 3)).

### Experimental Example 3

### Ep 3

An SRB layer having a Ge content of about 10 wt % was formed on a silicon substrate, and a Si—Ge layer having a Ge content of about 60 wt % was grown on the SRB layer. An initial compressive stress applied to the Si—Ge layer was measured.

Boron (B) was implanted into the Si—Ge layer by an ion-implantation process performed at a room temperature, and a compressive stress was measured. An SR % was calculated from the measured compressive stress and the initial compressive stress (Comparative Example 4 (Com 4)). Further, a thermal treatment using a laser at a temperature of about 900° C. was performed after the ion-implantation process, and then the SR % was calculated again (Comparative Example 5 (Com 5)).

An SR % was calculated in a condition substantially the same as that of Comparative Example 4 except that a temperature of the ion-implantation process was adjusted to about 300° C. (Example 4 (Ex 4)). Further, a laser annealing was performed at a temperature of about 900° C. after the ion-implantation process, and then the SR % was calculated again (Example 5 (Ex 5)).

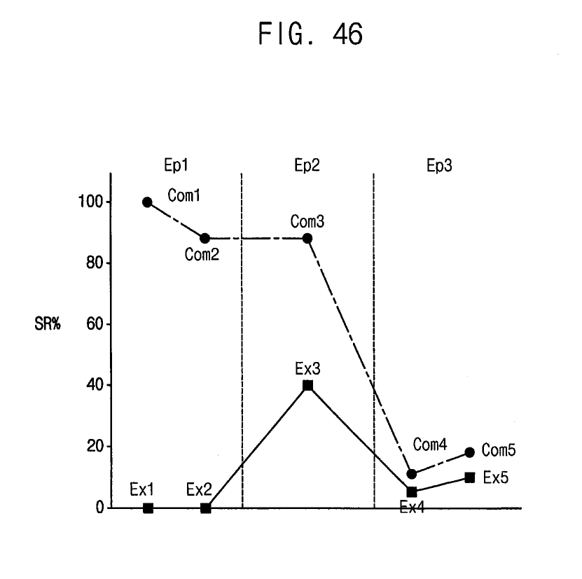

FIG. 46 is a broken-line graph showing values of a stress relaxation ratio measured by Experimental Examples.

Referring to FIG. 46, in Experimental Example 1, the calculated values of SR % in Comparative Examples 1 and 2 were nearly 100%. However, the calculated values of Examples 1 and 2 were substantially zero.

In Experimental Example 2, even though the Ge content was increased, and the annealing process was added, the SR % of Example 3 was about 40%. However, the SR % of Comparative Example 3 exceeded about 80%.

In Experimental Example 3, the SR % values were entirely reduced relatively to those in Experimental Example 2 by the presence of the SRB layer. The SR % values were less than about 10% in Examples 4 and 5. However, the SR % values of Comparative Examples 4 and 5 were greater than those of Examples 4 and 5.

According to example embodiments of the present inventive concept, a stress relaxation in a channel or a well may be suppressed by a high temperature ion-implantation. Thus, a charge mobility or an electron mobility may be increased so that operational properties of a transistor may be improved. For example, the methods in accordance with example embodiments may be effectively utilized for forming a well region, a source/drain region, a contact, etc., included in, e.g., a FinFET device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, comprising:
forming a stress channel layer on a semiconductor substrate;
performing a first ion-implantation process on the semiconductor substrate or the stress channel layer at a temperature ranging from about 100° C. to about 600° C.;
forming a gate structure on the stress channel layer; and
forming a first source/drain region at an upper portion of the stress channel layer adjacent to the gate structure.

2. The method of claim 1, wherein the stress channel layer includes silicon (Si), silicon-germanium (Si—Ge) or germanium (Ge).

3. The method of claim 2, further comprising, before forming the stress channel layer, forming a stress relaxation buffer layer including Si—Ge on the semiconductor substrate,
wherein the stress channel layer is grown from the stress relaxation buffer layer.

4. The method of claim 3, wherein the first ion-implantation process is performed on the stress relaxation buffer layer before forming the stress channel layer.

5. The method of claim 1, wherein the first ion-implantation process is performed at a temperature ranging from about 300° C. to about 500° C.

6. The method of claim 1, further comprising, after performing the first ion-implantation process, performing a thermal treatment on the stress channel layer at a temperature ranging from about 500° C. to about 1,000° C.

7. The method of claim 1, wherein forming the first source/drain region includes performing a second ion-implantation process on the stress channel layer at a temperature ranging from about 100° C. to about 600° C.

8. The method of claim 7, further comprising, after performing the second ion-implantation process, performing a third ion-implantation process by a predetermined tilting angle at a temperature ranging from about 100° C. to about 600° C. such that a halo region is formed at an upper portion of the stress channel layer adjacent to the first source/drain region and the gate structure.

9. The method of claim 7, further comprising:
growing an elevated source drain (ESD) layer from the first source/drain region; and
performing a fourth ion-implantation process on the ESD layer at a temperature ranging from about 100° C. to about 600° C.

10. The method of claim 9, wherein the ESD layer includes silicon, silicon carbide, silicon-germanium, germanium or germanium manganese.

11. A method of manufacturing a semiconductor device, comprising:
forming a stress channel layer defined by an isolation layer on a semiconductor substrate;
performing a first ion-implantation process on the stress channel layer at a temperature ranging from about 100° C. to about 600° C.;
removing an upper portion of the isolation layer to expose the stress channel layer such that a plurality of semiconductor fins are formed; and
forming a gate structure crossing the plurality of semiconductor fins, the gate structure extending in a direction.

12. The method of claim 11, further comprising:
forming a stress relaxation buffer layer before forming the stress channel layer on the semiconductor substrate;
partially etching the stress channel layer and the stress relaxation buffer layer to form a trench; and
forming the isolation layer filling the trench.

13. The method of claim 11, wherein forming the stress channel layer defined by the isolation layer includes:
forming the isolation layer at an upper portion of the semiconductor substrate to form a dummy active pattern;
removing the dummy active pattern to form a recess;
forming a stress relaxation buffer layer filling the recess;
removing an upper portion of the stress relaxation buffer layer to form a stress relaxation buffer layer pattern partially filling the recess; and
forming the stress channel layer on the stress relaxation buffer layer pattern, the stress channel layer filling a remaining portion of the recess.

14. The method of claim 11, further comprising:
forming a stress relaxation buffer layer before forming the stress channel layer on the semiconductor substrate;
partially etching the stress relaxation buffer layer to form a trench;
forming the isolation layer filling the trench;
removing an upper portion of the stress relaxation buffer layer to form a recess defined by a sidewall of the isolation layer and an upper surface of the stress relaxation buffer layer; and
growing the stress channel layer from the upper surface of the stress relaxation buffer layer, the stress channel layer at least partially filling the recess.

15. The method of claim 11, further comprising performing a second ion-implantation process on the plurality of semiconductor fins at a temperature ranging from about 100° C. to about 600° C. to form first source/drain regions at upper portions of the plurality of semiconductor fins adjacent to the gate structure.

16. The method of claim 15, further comprising:
growing an elevated source drain (ESD) layer from the first source/drain regions; and
performing a third ion-implantation process on the ESD layer at a temperature ranging from about 100° C. to about 600° C. to form second source/drain regions.

17. The method of claim 16, further comprising:
forming a preliminary contact layer on the second source/drain regions; and
performing a fourth ion-implantation process on the preliminary contact layer at a temperature ranging from about 100° C. to about 600° C. to form a contact electrically connected to at least one of the second source/drain regions.

18. The method of claim 17, further comprising:
forming an insulating interlayer covering the second source/drain regions and the gate structure; and
partially etching the insulating interlayer to form a contact hole, the contact hole exposing two neighboring second source/drain regions of the second source drain regions,
wherein the preliminary contact layer fills the contact hole.

19. A method of manufacturing a semiconductor device, comprising:
forming a plurality of active patterns defined by an isolation layer on a semiconductor substrate, the semiconductor substrate including a group III-V compound;
performing a first ion-implantation process on the plurality of active patterns at a temperature ranging from about 100° C. to about 600° C. such that upper portions of the plurality of active patterns are converted into a plurality of semiconductor fins; and
forming a gate structure crossing the plurality of semiconductor fins, the gate structure extending in a direction.

20. The method of claim 19, further comprising performing a second ion-implantation process on the semiconductor fins at a temperature ranging from about 100° C. to about 600° C. using the gate structure as an implantation mask to form a source/drain region.
